(19) United States
(12) Patent Application Publication
(10) Pub. No.: US 2003/0233630 A1
(43) Pub. Date: Dec. 18, 2003

(54) Methods and systems for process control of corner feature embellishment

(76) Inventors: Torbjorn Sandstrom, Pixbo (SE); Hans Martinsson, Goteborg (SE); Niklas Eriksson, Savedalen (SE); Jonas Hellgren, Goteborg (SE)

Correspondence Address: HAYNES BEFFEL & WOLFELD LLP, P O BOX 366, HALF MOON BAY, CA, 94019, US

(21) Appl. No.: 10/410,874

(22) Filed: Apr. 10, 2003

Related U.S. Application Data
(63) Continuation-in-part of application No. PCT/SE02/02310, filed on Dec. 11, 2002.
(60) Provisional application No. 60/415,509, filed on Oct. 1, 2002.
(60) Provisional application No. 60/444,417, filed on Feb. 3, 2003.
(60) Provisional application No. 60/455,364, filed on Mar. 17, 2003.

(30) Foreign Application Priority Data
Dec. 14, 2001 (SE) 0104238-1

(51) Int. Cl. G06F 17/50; G03F 9/00

(52) U.S. Cl. 716/19; 430/5

(57) ABSTRACT

The present invention relates to methods and systems that embellish corner features (inside and outside) under process control to correct for optical proximity and other effects in generating patterns on workpieces. Workpieces include lithographic masks and integrated circuits produced by direct writing. Particular aspects of the present invention are described in the claims, specification and drawings.

### PRIORITY CLAIMS

This application claims the benefit of provisional Patent Application No. 60/415,509, entitled “Resolution Extensions in the Sigma 7000 Imaging SLM Pattern Generator” by inventors Torbjörn Sandström and Niklas Eriksson, filed on Oct. 1, 2002; No. 60/444,417, entitled “Further Resolution Extensions for an SLM Pattern Generator” by inventors Torbjörn Sandström and Niklas Eriksson, filed on Feb. 3, 2003; and No. 60/455,364, entitled “Methods and Systems for Process Control of Corner Feature Embellishment” by inventors Torbjörn Sandström, Hans Martinsson, Niklas Eriksson and Jonas Hellgren, filed on Mar. 17, 2003; and further claims priority as a continuation-in-part of the international application designating the United States submitted and to be published in English, Application No. PCT/SE02/023 10, entitled “Method and Apparatus for Patterning a Workpiece” by inventors Torbjörn Sandström, filed on Dec. 11, 2002 and claiming priority to the Swedish Application No. 0104238-1 filed on Dec. 14, 2001. These three provisional applications and the international application are hereby incorporated by reference.

### RELATED APPLICATIONS

This application is related to the commonly owned U.S. patent application No. 09/954,721, entitled “Graphics Engine for High Precision Lithography” by inventors Martin Olsson, Stefan Gustavson, Torbjörn Sandström and Per Elmfors, filed on Sep. 12, 2001, which is hereby incorporated by reference (“Graphics Engine application”). It is further related to U.S. patent application Ser. No. 10/238,220, entitled “Method and Apparatus Using an SLM” by inventors Torbjörn Sandström and Jarek Luberek, filed on Sep. 10, 2002 which claims the benefit of provisional Patent Application No. 60/323,017 entitled “Method and Apparatus Using an SLM” by inventors Torbjörm Sandström and Jarek Luberek, filed on Sep. 12, 2001, which are hereby incorporated by reference. It is also related to U.S. patent application Ser. No. 09/992,653 entitled “Reticle and Direct Lithography Writing Strategy” by inventor Torbjörn Sandström, filed on Nov. 16, 2001 which is a continuation of application Ser. No. 90/665,288 filed Sep. 18, 2000, which '653 application is hereby incorporated by reference (“Writing Strategy application”).

### BACKGROUND OF THE INVENTION

The present invention relates to methods and systems that embellish corner features (inside and outside) under process control to correct for optical proximity and other effects in generating patterns on workpieces. Workpieces include lithographic masks and integrated circuits produced by direct writing. Particular aspects of the present invention are described in the claims, specification and drawings.

Transferring a logic circuit design onto a substrate and creating an integrated circuit involves many steps, from logic design to circuit layout, addition of embellishments to correct for proximity or other effects, and process control during generation of patterns. Logic designs are increasingly complex. Part of creating a logic design is the circuit layout, which proceeds as part of the logic design process because many operating characteristics of an integrated circuit depend on the distance the signal must travel and the resistance that it encounters. The logic circuit design and layout typically proceed in a vector domain, because vector data is more convenient for design purposes and more compact.

Once the circuit is laid out, a process is selected for generating masks to be used in printing layers of the circuit or for direct writing layers of the circuit. To support direct writing, embellishments are often added to the circuit layout to correct for proximity effects. These proximity effects include optical proximity effects or e-beam proximity effects that relate to a Gaussian or other distribution of radiant energy, that is, photon or e-beam energy, respectively. For instance, when photon energy is used in a pattern generator, one or more embellishments may be added to corners of a contact point to make the contact point more nearly square and to avoid the rounding associated with the Gaussian distribution of photon energy. These are so-called optical proximity correction features. Similarly, one or more embellishments may be added to inside corner features, to “L” shaped patterns, to reduce fill-in associated with the Gaussian distribution. Embellishments added to either inside or outside corner features do not themselves typically appear in the resulting exposure pattern on the wafer, after development. Instead, they influence the pattern that appears in a developed layer of resist.

To support lithographic writing with masks, embellishments may be added to embellishments. These are so-called lithographic proximity correction features. It typically is desirable for a mask to include inside and outside corner embellishments and other features that will affect the distribution of radiant energy projected through the mask onto a workpiece and the pattern that is generated on the workpiece. To generate a mask that includes the desired embellishment shapes, embellishments may be added to corners of the desired embellishment shapes so that they are accurately produced on the surface of the mask. Of course, adding embellishments upon embellishments greatly increases in vector complexity of the circuit layout. For instance, a, single outside corner with an embellishment may become two inside corners and three outside corners, as illustrated in FIG. 2A. The same corner with embellishments upon an embellishment may become 12 inside corners and 13 outside corners, as illustrated in FIG. 2B. The fab responsible for generating a pattern on an integrated circuit may have a variety of process controls to influence the pattern that appears in developed resist. Process controls include characteristics of the resist to be exposed, exposing radiation, development after exposure, etching, and other process conditions. While logic circuit design is complex, producing an integrated circuit based on the logic design introduces much further complexity.

The performance requirements of photomasks for IC manufacturing have gradually increased as the so-called k1 factor of photolithography has decreased. As a consequence of tighter specifications, increased use of advanced OPC and the introduction of hard phase shift masks, pattern fidelity has become tightly connected to the IC design and manufacturing process. Development and qualification of new manufacturing processes require determination of the OPC models and mask properties early in the process. However, as production ramps up, an effect is a lock-in to potentially expensive and long lead-time mask supply chains.

Of the two main types of radiant energy used to generate patterns, a photon beam typically has a wider cross-section than an electron beam. Systems using multiple photon beams are more generally available than systems using multiple electron beams. Photon or laser pattern generator systems usually are faster but less precise than e-beam systems. Multiple, relatively wide beams in a laser scanning system have different characteristics, including less precision than a single electron beam in a vector-driven e-beam system. Embellishments upon embellishments can be used in mask writing with a laser scanning system to compensate partially for the larger beam width of the photon beam.

For direct writing applications, photon-exposing radiation may be preferred, because an electron beam may adversely affect layer properties of the integrated circuit. Both at the substrate and in electron charge-trapping layers of the integrated circuit, electrons that pass through a resist layer that is being patterned may damage or change characteristics of the layer below the resist. These modified characteristics may have undesirable effects on device performance.

These inventors are working on development of a new kind of pattern generator that uses photon-exposing radiation. Instead of using one or more scanned laser beams, the new kind of pattern generator uses a spatial light modulator (“SLM”) and a pulsed illumination source to print so-called stamps across the face of a workpiece. The Graphics Engine application referenced above is one of several applications with overlapping inventors that disclose aspects of this new kind of pattern generator. These co-pending applications also teach that other kinds of arrays that may be used with pulsed illumination to print stamps.

Some types of embellishments used to correct for optical proximity effects have been described in the prior art. For instance, serifs, anti-serifs and hammerheads are depicted in FIG. 1B of U.S. Pat. No. 6,453,457. Adjacent features which are at risk of bleeding in teach other and not printing has distinct layout pass are depicted in the same patent, FIG. 1A and in U.S. Pat. No. 5,340,700, FIG. 1C. Simple geometric figures, such as squares, rectangles and triangles appear in these depictions because more complex geometric figures, such as ellipses, would be impractical to represent or reproduce in systems designed to handle the simple geometric figures.

An opportunity arises to improve production flexibility by adding user-modifiable parameters to mask making and direct writing pattern generators. It would be desirable to modify process parameters without changing the underlying vector pattern database to adjust the exposure at corner features. For instance, it would be desirable for process parameters to compensate for developer and edge bias, or to modify contact area, corner pullback and line shortening. It also may be desirable for process parameters to adjust the operating characteristics of the pattern generator to match the characteristics of a different type of pattern generator, for instance to match the operating characteristics of a new kind of SLM-based pattern generator to a well-understood and established e-beam machine.

### SUMMARY OF THE INVENTION

The present invention relates to methods and systems that embellish corner features (inside and outside) under process control to correct for optical proximity and other effects in generating patterns on workpieces. Workpieces include lithographic masks and integrated circuits produced by direct writing. Particular aspects of the present invention are described in the claims, specification and drawings.

### BRIEF DESCRIPTION OF THE DRAWINGS

FIG. 1 depicts the general layout of an SLM pattern generator.

FIG. 2 illustrates process adjustment to modify the pattern that appears in developed resist without changing the underlying vector pattern database.

FIG. 3 depicts various corner patterns produced by various distributions of exposing radiation.

FIG. 4 depicts different patterns of multi-pass writing to generate a pattern.

FIG. 5 illustrates illumination patterns, before and after adjustment, for an isolated corner feature exposed in four writing passes.

FIGS. 6 and 7 illustrate alternate embodiments of using an exposure adjustment profile.

FIGS. 8-10 illustrate embellishments that can be dynamically added to corner features.

FIG. 11 illustrates details of one embodiment of an exposure adjustment profile.

FIG. 12 illustrates features of a line end with a plurality of embellishments.

FIG. 13 illustrates a method for analysis of manipulating process parameters to match an embellishment produced by an e-beam machine.

FIGS. 14-18 depict portions of simulation results produced by manipulating process parameters for an outside corner.

FIG. 19 depicts exposure curves and deviations between curves and a reference curve.

FIGS. 20-21 are portions of a Matlab program code used to produce an exposure adjustment profile and simulation results.

FIG. 22 depicts a geometric analysis of characteristics a multipass writing strategy.

FIG. 23 depicts exposure of line ends and sensitivity to corner placement within a pixel square grid.

### DETAILED DESCRIPTION

The following detailed description is made with reference to the figures. Preferred embodiments are described to illustrate the present invention, not to limit its scope, which is defined by the claims. Those of ordinary skill in the art will recognize a variety of equivalent variations on the description that follows.

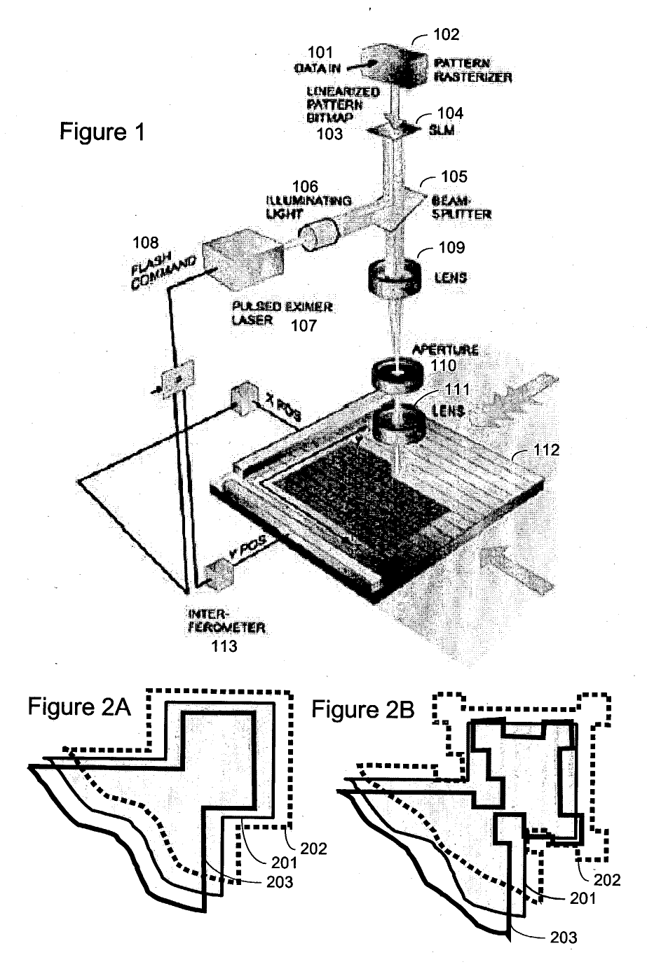

FIG. 1 depicts the general layout of an SLM pattern generator. Aspects of an SLM pattern generator are disclosed in the related-pending patent applications identified above. The workpiece to be exposed sits on a stage 112. The position of the stage is controlled by precise positioning device, such as paired interferometers 113. The workpiece may be a mask with a layer of resist or other exposure sensitive material or, for direct writing, it may be an integrated circuit with a layer of resist or other exposure sensitive material. In the first direction, the stage moves continuously. In the other direction, generally perpendicular to the first direction, the stage either moves slowly or moves in steps, so that stripes of stamps are exposed on the workpiece. In this embodiment, a flash command 108 is received at a pulsed excimer laser source 107, which generates a laser pulse. This laser pulse may be in the deep ultraviolet (DUV) or extreme ultraviolet (EUV) spectrum range. The laser pulse is converted into an illuminating light 106 by a beam conditioner or homogenizer. A beam splitter 105 directs at least a portion of the illuminating light to an SLM 104. The pulses are brief, such as only 20 ns long, so any stage movement is frozen during the flash. The SLM 104 is responsive to the datastream 101, which is processed by a pattern rasterizer 102. In one configuration, the SLM has 2048×512 mirrors that are 16×16 μm each and have a projected image of 80×80 nm. It includes a CMOS analog memory with a micro-mechanical mirror formed half a micron above each storage node. The electrostatic forces between the storage nodes and the mirrors actuate the mirrors. The device works in diffraction mode, not specular reflectance, and needs to deflect the mirrors by only a quarter of the wavelength (62 nm at 248 nm) to go from the fully on state to the fully off state. To create a fine address grid the mirrors are driven to on, off and 63 intermediate values. The pattern is stitched together from millions of images of the SLM chip. Flashing and stitching proceed at a rate of 1000 stamps per second. To eliminate stitching and other errors, the pattern is written four times with offset grids and fields. Furthermore, the fields are blended along the edges. The mirrors are individually calibrated. A CCD camera, sensitive to the excimer light, is placed in the optical path in a position equivalent to the image under the final lens. The SLM mirrors are driven through a sequence of known voltages and the camera measures the response. A calibration function is determined for each mirror, to be used for real-time correction of the grey-scale data during writing. In the data path, the vector format pattern is rasterized into grey-scale images, with grey levels corresponding to dose levels on the individual pixels in the four writing passes. This image can then be processed using image processing. The final step is to convert the image to drive voltages for the SLM. The image processing functions are done in real time using programmable logic. Through various steps that have been disclosed in the related patent applications, rasterized pattern data is converted into values 103 that are used to drive the SLM 104.

In this configuration, the SLM is a diffractive mode micromirror device. A variety of micromirror devices have been disclosed in the art. In an alternative configuration, illuminating light could be directed through a micro-shutter device, such as in LCD array or a micromechanical shutter.

An SLM pattern generator, such as a mask writer or direct writer that uses a grey-scale sampled image enables a variety of enhancement schemes. The grey value of each pixel is an area sample value of the pattern. Taking into account the imaging properties of the tool and a desired response, such as a specific corner radius, adjustments of the exposure values in a predetermined vicinity of a corner feature can be used to mimic or match the properties of another pattern generator, such as the exposed corner radius and corner pull back. The adjustment recipe can be adapted to match, for instance, another mask writer. To do this, exposed pattern properties in resist on workpieces of the two pattern generators can be compared. The comparison can be based on simulation, developed resist or latent images in resist. The exposure may be produced either directly by the pattern generators or indirectly by masks produced using the pattern generators. Comparison of the exposed patterns allows adjustment of one or more process control parameters until the exposed patterns essentially match. Data is modified in the raster domain of at least one of the pattern generators according to the process control parameters, rather than modifying vector-based pattern data in the design domain. The process control parameters may relate to corner feature exposure properties.

FIG. 2 illustrates process adjustment to modify the pattern that is generated on a workpiece or appears in developed resist or other exposure-sensitive material. This process adjustment can be made without changing the underlying vector pattern database. In both FIGS. 2A and 2B, the desired pattern is indicated by the shaded outline 201. In both figures, the desired pattern is a corner with an embellishment. In FIG. 2A, the desired pattern is used for pattern generation without further embellishment. In FIG. 2B, further embellishments are added to the embellishment to generate an exposed feature or a developed pattern in resist that more closely approximates the desired pattern than would be expected from writing the pattern directly. Process control is indicated by outlines 203 and 202, which depict different sizes of exposing radiation that might be projected to generate the desired pattern after resist development and etching.

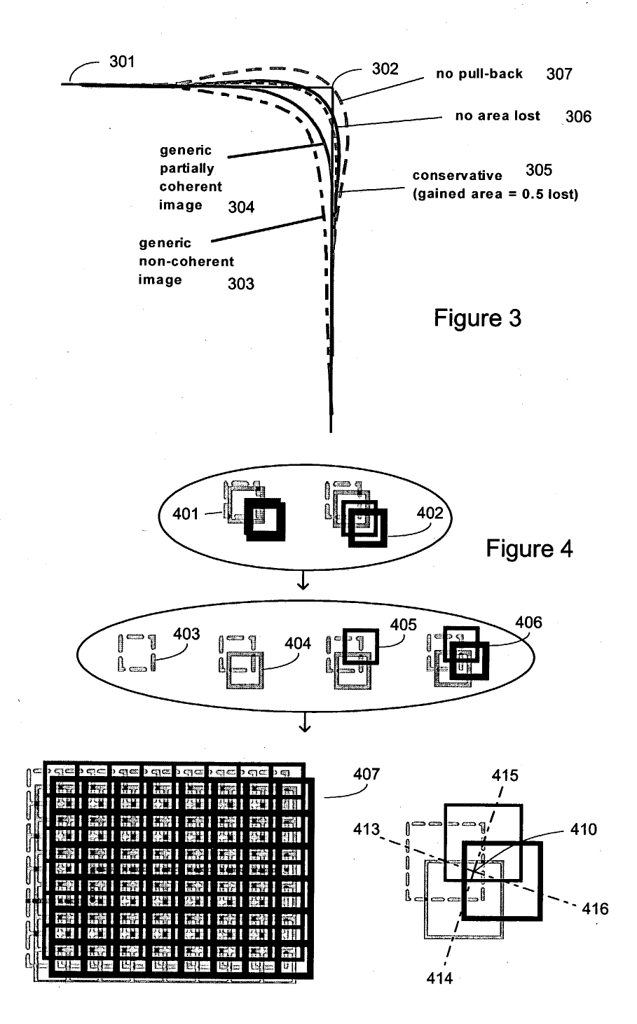

FIG. 3 depicts various corner patterns produced by Gaussian or other distributions of exposing radiation. The desired corner 302 is at the intersection of solid lines 301. It is a 90-degree corner of a rectangle, for instance. Gaussian distributions of exposing radiation can produce a variety of curves that approximate the desired corner. A generic non-coherent image produced using photon radiation is depicted by curve 303. A generic partially coherent image produced using photon radiation is depicted by curve 304. Curves 305-307 represent modified image curves having various characteristics. Curve 305 is a conservative modified image with a small amount of area loss and a modest bulge outward from the desired line 301 as it approaches the corner. Curve 306 is a curve that matches the area of the desired corner 302, with the bulge outward and a pullback at the corner 302. Curve 307 has no pullback at the corner 302, but has an increased area because it is a curve, not a sharp corner. Parametric process control may allow an operator to select among these curve profiles. According to one aspect of the present invention, a range of process control parameters can be applied to the single test workpiece for evaluation and selection.

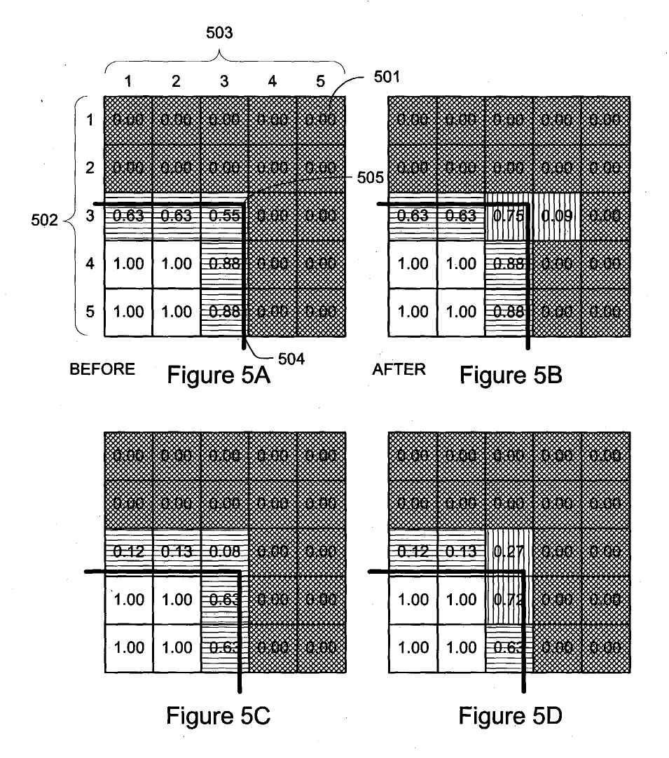

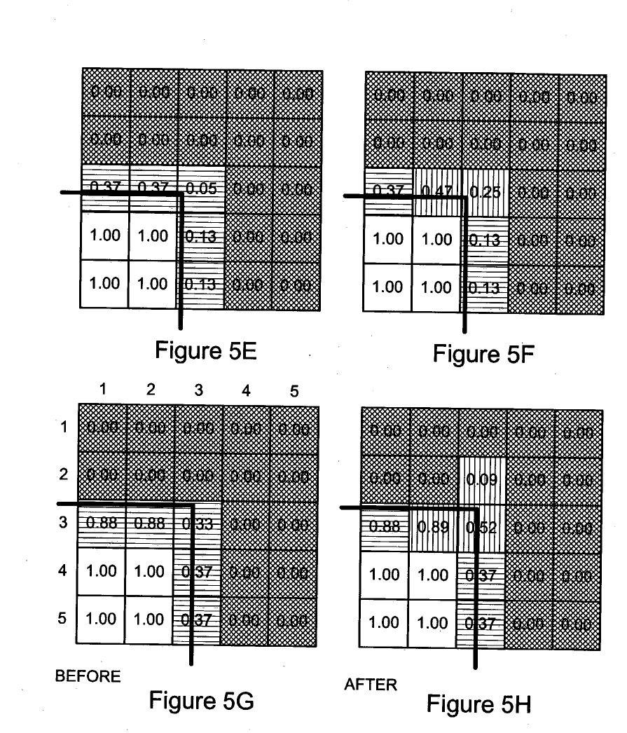

It is anticipated that the present invention will be applied in conjunction with a multi-pass writing strategy. A variety of multi-pass writing strategies could be used, as illustrated in FIG. 4. Two different strategies are illustrated by 401 and 402. In each of these depictions, the first writing pass is indicated by a grey dotted line, the second writing pass by a grey solid line, the third writing pass by a narrow black line and the fourth writing pass by a wider black line. The multipass strategy illustrated by 401 involves two closely staggered exposures, a significant offset and two additional closely staggered exposures. These closely staggered exposures might be generated in two or four physical writing passes. The multipass strategy illustrated by 402 involves equally staggered exposures cascaded along an axis that is transverse to axes, aligned to the edges of the exposed pattern. A novel multipass strategy is illustrated by the progression 403-406. To implement the strategy, vector data is rasterized four separate times. The pattern of staggered exposures is revealed by references 410 and 413-416. These references deconstruct the staggered pattern. The four exposures overlap in a region centered at 410. The centers of four exposures are uniformly distributed in a radial pattern about the center 410, so that the lines 413-406 and 404-405 form a rotated axis pair. Moreover, the centers of the four exposures are equidistant from the center 410. That is, the center of exposure 403 along axis 413 is the same distance from center 410 as the centers of exposures 404, 405 and 406 along axes 414, 415 and 416, respectively. This progression of staggered exposures may be characterized as directionally isotropic, in that there is no single vector along which the staggering proceeds. The progression of centers of exposures 403-406 is a “Z” pattern and not in a rotation around the center 410. (First, adjacent, opposite, last.) One of skill in the art will understand that the order in which these writing passes are applied may be varied. Another progression of centers of exposures 403-406 would be in a rotation around the center 410, as depicted in FIG. 5. (First, adjacent, adjacent to adjacent, last.) The third progression of pixel centers might be 403, 406, 404, 405, resembling the pattern for tightening bolts on a car tire or engine head. (First, opposite, third, last.) Three, four, five, six, seven, eight or more passes, preferably an even number of passes, can also be uniformly distributed on an angular basis about the center of overlaps 410. An even number of passes is preferred to facilitate writing in opposite directions and with essentially equal average time from exposure to development across the face of the mask, as disclosed in the Writing Strategy application. At least three exposures are staggered to produce axes through pixel centers that are not coincident. The writing strategy disclosed tends to hide the grid on which data is placed and soften the artifacts of rasterization. A larger grid of staggered exposures is also illustrated 407. All examples show four exposure passes, but staggered offset passes are also possible using 3, 5, 6, 7, 8 or more passes.

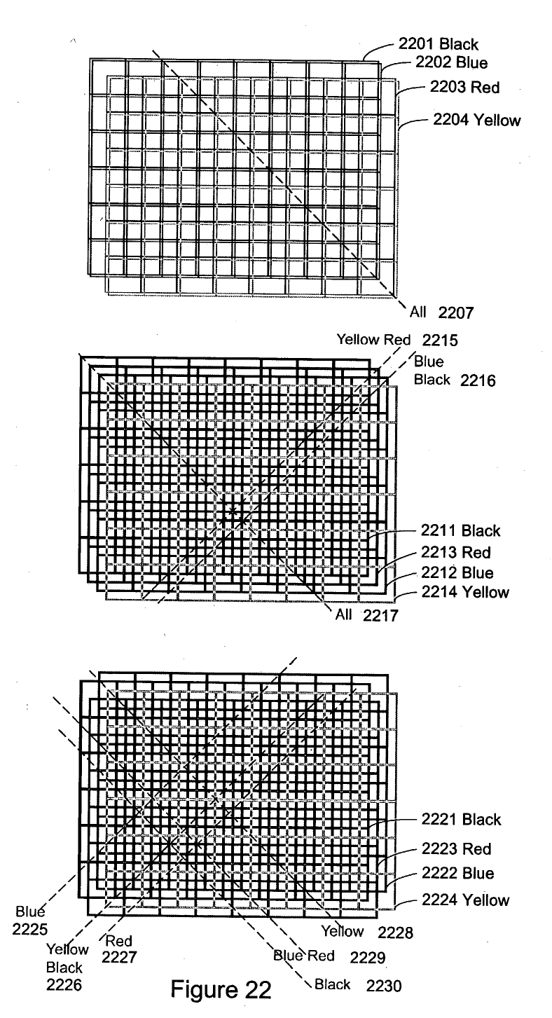

A geometric analysis of characteristics of the stagger 403-406 appears in FIG. 22. It will be understood by those of skill in the art that these square grids represent a logical organization, rather than an exposed pattern in resist, due to a Gaussian or other distribution of exposing radiation. This analysis shows that the stagger pattern 403-406 is more directionally isotropic than patterns 401, 402 in FIG. 4. In the three patterns, the exposure passes are numbered 2201-04, 2211-14 and 2221-24. The first pattern, corresponding to 401 in FIG. 4, aligns the centers of pixels in all four passes along an axis 2207. The second pattern, corresponding to 402 in FIG. 4, aligns the centers of pixels in all for passes along an axis 2217. That is, in the first and second patterns, diagonal axes constructed through the centers of pixels in each of the respective exposure passes are coincident for all four exposure passes. In the second pattern, additional diagonal axes 2215, 2216 constructed through the centers of pixels are perpendicular to axis 2217. Only two independent, non-coincident axes are constructed through the centers of pixels exposed in four exposure passes. The third pattern corresponds to 403-406 in FIG. 4. Along either a 45 or 135 degree diagonal, three or more sets of parallel, non-coincident axes can be constructed through the centers of pixels exposed in four exposure passes. The axes 2226 and 2229 each pass through the centers of pixels exposed in two passes, but no axis passes through the centers of pixels exposed in three passes. Four writing passes produce three non-coincident axes at the 0, 45, 90, and 135 degree orientations. Similar diagrams can be constructed for 3, 5, 6, 7, 8 or more passes, applying directionally isotropic exposure.

FIG. 5 illustrates illumination patterns, before and after adjustment, for a single corner feature exposed in four writing passes. The writing passes depicted in FIGS. 5A-5H present an alternate order for staggering the writing passes of 403-406. In these illumination patterns, an array of individual pixels 501 is numbered by row 502 and column 503. Dark pixels, such as 1,1, are crosshatched and numbered “0.00”. Bright pixels, such as 5,1, are numbered “1.00”. Grey-shaded pixels are indicated by horizontal or vertical bars and given a value between 0.00 and 1.00. Horizontal bars are used for grey-shaded pixels in each of the “before” adjustment figures and for a grey-shaded pixels that do not change in the “after” adjustment figures. Vertical bars are used in “after” adjustment FIGS. 5B, 5D, 5F and 5H, to indicate grey-shaded pixels that have been adjusted. In each of the figures, a corner 505 is depicted, at the intersection of two edges 504. The exposed location of the edge 504 and corner 505 in developed resist roughly corresponds to the grey fraction of the cell. For instance, in FIG. 5A, the edge 504 in cell 5,3 is approximately seven-eighths of the way from the bright cell 5,2 to dark cell 5,4, corresponding to a grey fraction of 0.88. In FIG. 5B, the result of the adjustment in a predetermined vicinity of the corner 505 is that cell 3,3 brightened from 0.55 to 0.75 and cell 3,4 brightened from 0.00 to 0.09. The same corner, in the writing pass depicted by FIGS. 5C-5D is staggered from the writing pass in the preceding figures, so the grey-shaded cells have different grey fractions. In this writing pass, cells 3,3 and 3,4 have adjusted grey fractions. The reader is cautioned not to attempt to scale from these figures. While the grey fractions reflect a calculated adjustment, the placement of the corner in cell 3,3 of the figures is illustrative only, partially chosen to avoid obscuring the grey fractions.

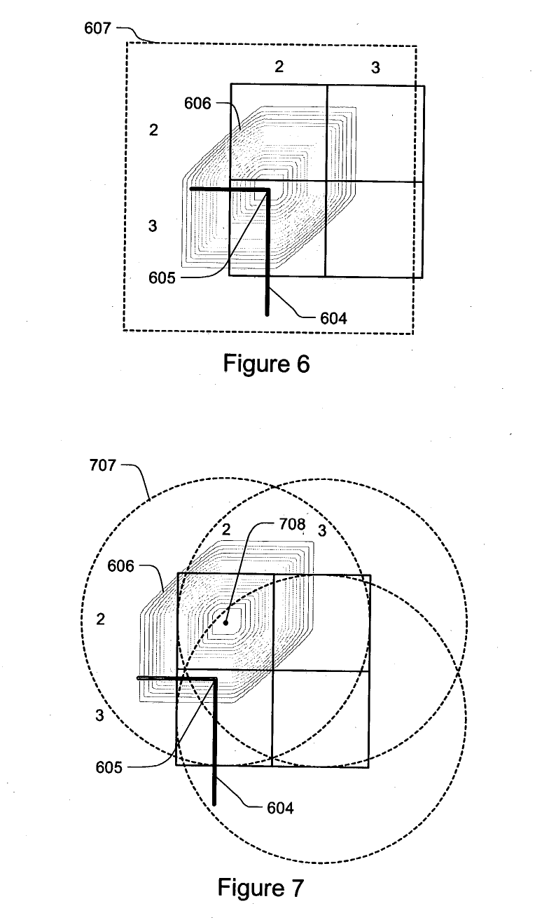

FIGS. 6, 7, 20 and 21 provide additional details of calculating adjusted grey fractions in FIG. 5. FIG. 6 illustrates a corner-centric method embodiment. In this figure, the corner 605 is surrounded by a predetermined vicinity 607. Each cell is 80 nm square. The predetermined vicinity 607 is 120 nm square from the corner feature in each direction or 240 nm square, centered at the corner feature. In one embodiment, cells or pixels are selected whose centers fall within the predetermined vicinity of the corner 605. Cells 2,3, 2,2, 3,2 and 3,3 are among the selected cells. A corner vicinity adjustment profile 606 is applied to determine cell adjustments. In FIG. 6, the center of cell 3,2 is near the center of the profile. The center of cell 2,2 is somewhat further from the center of the profile. Neither the center of cell 2,3 or cell 3,3 falls within the profile. Application of the corner vicinity adjustment profile 606 produces the result depicted in FIG. 5H as modified grey fractions.

FIG. 7 illustrates a pixel center-centric method embodiment. Of course, the distance between two points is the same, whether measured from a first point to a second point, or vice versa. In this embodiment, any corner 605 within the predetermined vicinity of a cell center 708 is selected. The predetermined vicinity 707 in this illustration is within a distance depicted by the radius of a circle. The corner vicinity adjustment profile 606 is applied from the pixel center 708. The corner 605 is three-quarters of the way from the center to the edge -of the corner vicinity adjustment profile.

The methods in both FIGS. 6 and 7 can be modified by sliding the adjustment profile in or out along the corner bisector. That is, the corner or the center of the pixel is aligned with the major or minor axis of the adjustment profile, but not necessarily coincident with the center of the adjustment profile. This may change the preferred size of the predetermined vicinity.

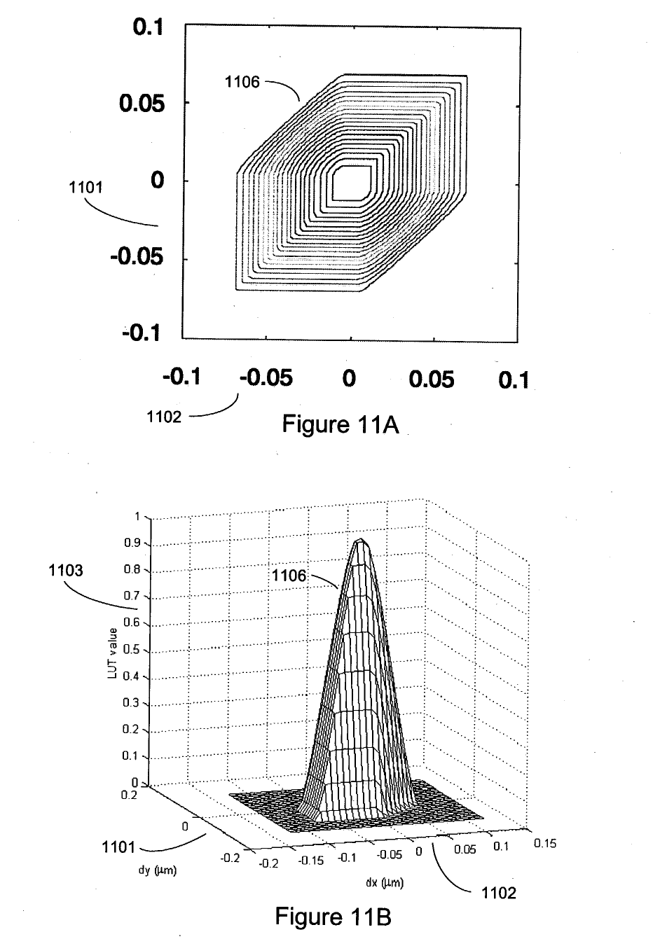

FIG. 11 includes a plan view and an isometric view of one corner vicinity adjustment profile. In order to continuously tune the corner pull back and to minimize the area loss at corners, the exposure distribution near corner features must be modified. In case of a bright isolated contact corner, exposure intensity must be added in order to stretch the iso-intensity curve out towards the corner. For an island or inside corner, light must be subtracted. There are many ways in which this can be accomplished. The grey level values of pixels in a predetermined vicinity of the corner feature are adjusted in a well-controlled manner.

Several considerations impact adjustment profile embodiments of the present invention. First, implementation resources and algorithm complexity increase with an increasing physical extent of the predetermined vicinity that is analyzed and adjusted. A very small predetermined vicinity would limit the performance of the adjustment. A large vicinity could delay development until more powerful processors became available at a reasonable cost. A vicinity of three by three pixels, or 240 by 240 nm, is a reasonable compromise, given presently available resources. A vicinity of five by five pixels could be used instead. Second, some adjustment profiles produce different results depending on where a corner feature falls in a pixel. A corner feature near the center of a pixel may be handled better or worse than a corner feature near an edge or corner of a pixel. Third, both inside and outside corners require illumination adjustment. Isolated and dense corners are likely to be found in a design. Positive and negative resist, in which features are exposed or left unexposed, are used in various processes. Fourth, a larger dynamic range of adjustments will accommodate more uses.

In FIGS. 11A-11B, a diamond-shaped three-dimensional surface 1106 was derived by cross-correlation of an ellipse and square, as described below. In these figures, the x and y axes 1102, 1101 are scaled in microns. The long and short half-axes of the diamond-shaped profile are 107 and 58 mn, respectively. That is, along the long axis, the profile has a reach of 107 um. The height of the profile 1103 ranges from 0 to 1, subject to scaling by application of the gli or glo factors. Through cross-correlation, the effect of the pixel size and the profile of the embellishment to be dynamically added are merged. The resulting profile takes into account the effect of the pixel size and, therefore, is virtually independent of where the corner falls within the pixel. In the absence of additional features in close proximity to the corner feature being embellished, this profile is completely corner position independent. It is anticipated, under real conditions, that closely adjacent features will invoke overlapping profiles in some instances, which somewhat reduces the position independence of this profile, but ends to favor high aspect ratio embellishments or profiles.

An ellipse oriented on a transverse axis is one way to concentrate the area of modified pixel values along a corner bisector. This is desirable for so-called Manhattan geometries with horizontal and vertical edges. It minimizes the extent to which the profile overlaps with profiles applied to adjacent corners. In the direction of the long axis, the extent of the profile will determine the integrated contribution of the profile. In order to allow for a large tuning range of corner radius and pull back, the long axis length should be large. By trial and error with a particular pixel-oriented system, a semimajor axis length of 107 nm was selected, as a good compromise between tuning range, overlaps from adjacent corners, and performance on both isolated and dense corners.

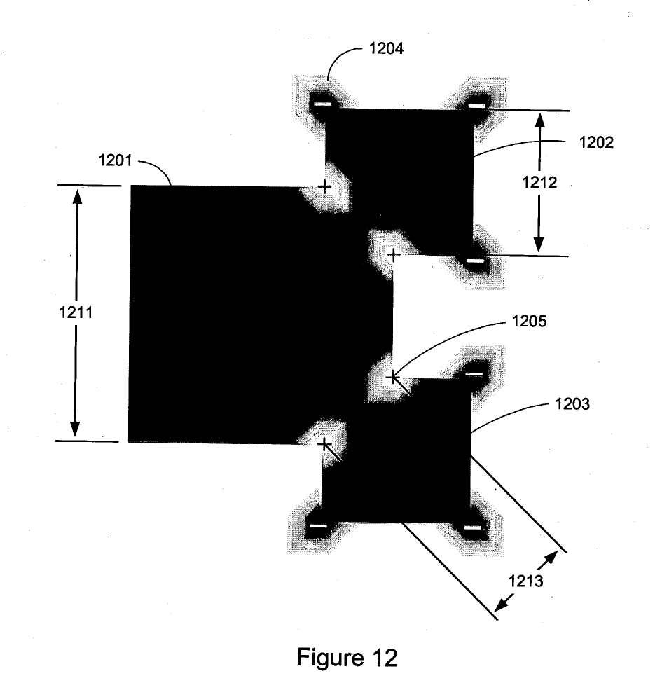

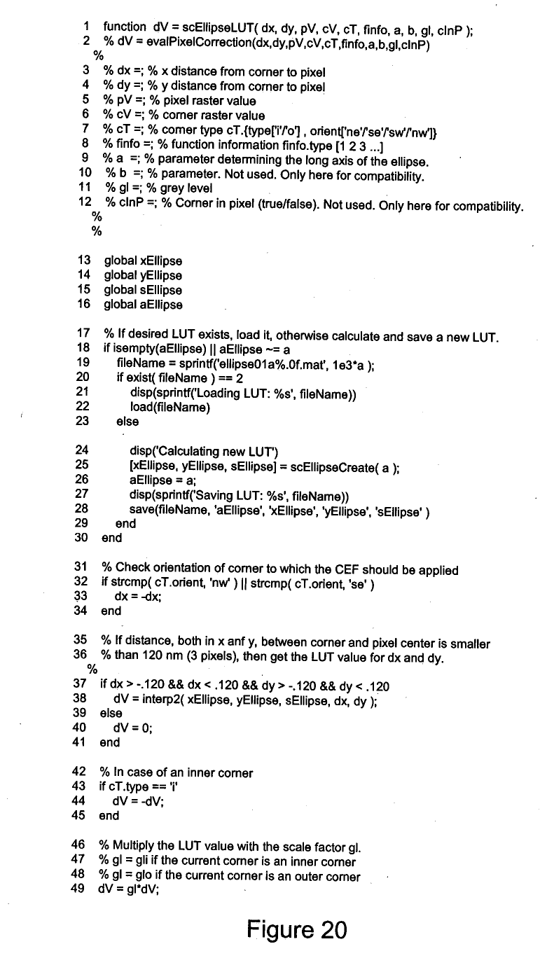

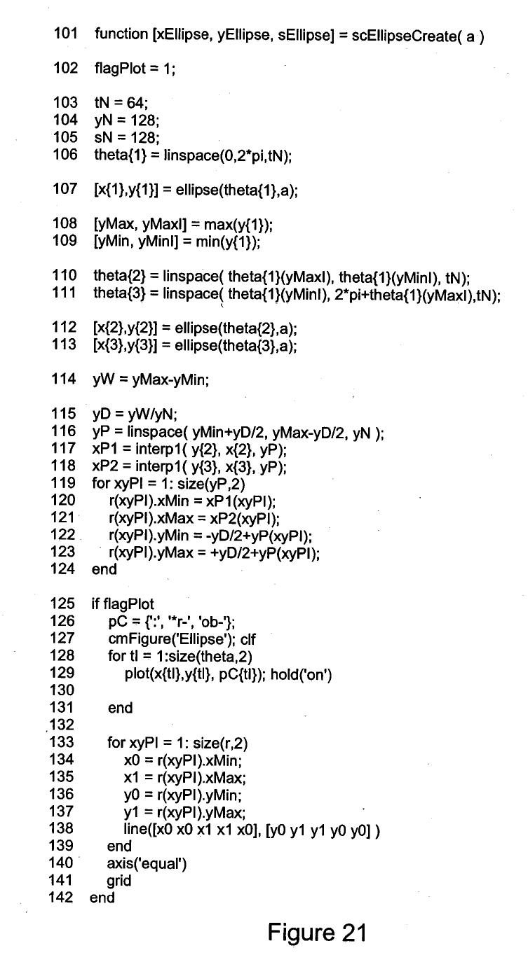

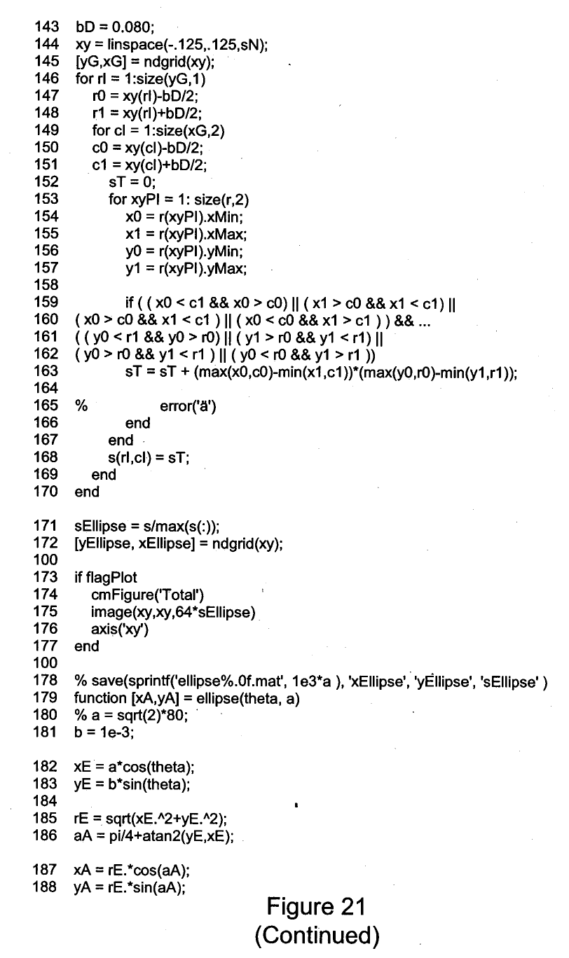

One embodiment of the adjustment profile is a lookup table. The function illustrated in FIGS. 11 and 12 and implemented in FIGS. 20 and 21 represents a cross-correlation between an ellipse with major and minor semiaxes of 50 and 1 nm, and a square approximately the same size as a pixel (80 by 80 nm in this example). The definition of a two-dimensional cross-correlation between two functions f(x,y) and g(x,y) is defined as:

$$h ( x , y ) = {\int }_{- ∞}^{∞} {\int }_{- ∞}^{∞} f ( {x}^{′} , {y}^{′} ) g ( x + {x}^{′} , y + {y}^{′} ) ⅆ {x}^{′} ⅆ {y}^{′}$$

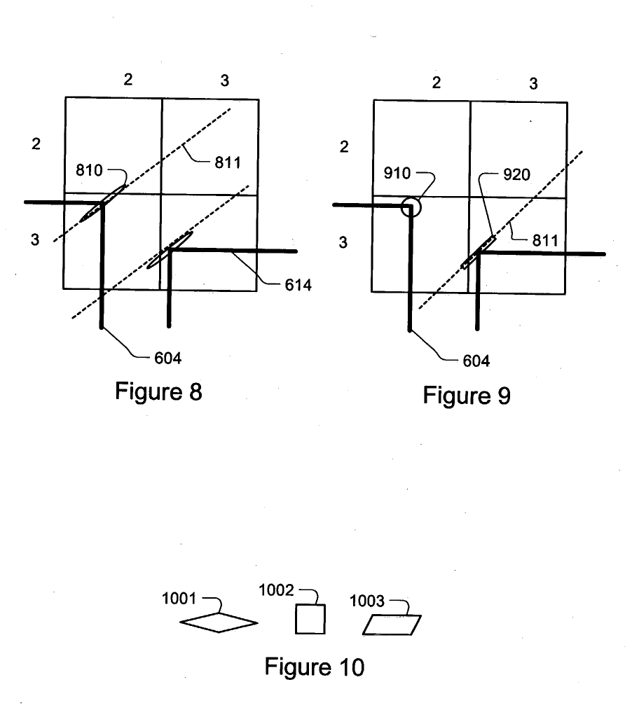

In this example, f(x,y) is the ellipse, having major and minor axes or semimajor and semiminor axes of 50 and 1 nm and rotated 45 degrees, as generally illustrated in FIG. 8, ellipse 810. The function g(x,y) is the 80 by 80 nm square corresponding to the projected image of a pixel in this embodiment. The resulting cross-correlation h(x,y) is equal to the area overlap between the square, g(x,y), and the ellipse, f(x,y), when the square is displaced by distance (x,y). These values are then multiplied with a factor gli or glo to scale the adjustments of inside and outside corners, respectively.

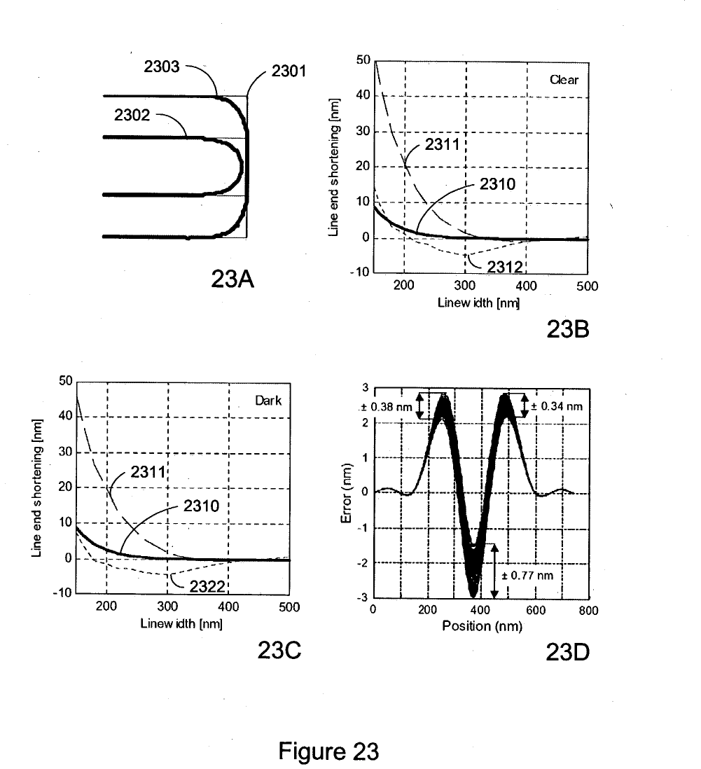

Sensitivity analysis was performed to determine whether this adjustment profile is sensitive to the initial location of a corner within a pixel. The desirability of corner position independence is mentioned above. In general, the greatest corner position sensitivity was when the corner feature coincided with a bisector or diagonal axis of the pixel. The uncertainty created for such corner placement was approximately +/−0.9 nm in one simulation. FIG. 23D depicts results of a simulation performed as part of the sensitivity analysis. The results show that one adjustment profile produced adjustments for an isolated corner that were generally insensitive to where the corner feature falls in a pixel. FIG. 23D includes edge contours extracted from aerial image simulation plots of corner enhancement for 100 corners placed at random corner locations within a pixel grid square. The corner location within a pixel dependence illustrated by this figure is negligible. Regardless of where the corner falls within a pixel grid square, the corner enhancement produces very nearly the same adjusted curve. A maximum uncertainty resulting from corner placement within a pixel grid square was better than plus or minus 1 nm, as measured by the range of deviation among aerial images produced by adjusted exposures and the reference curve for 100 random corner placements within a pixel grid square. Expressed as a fraction, the maximum displacement uncertainty resulting from corner placement within a pixel area is less than two percent of the pixel width.

FIGS. 20 and 21 depict portions of a Matlab program used to construct and apply a corner vicinity adjustment profile. FIG. 20 is a function scEllipseLUT that can be called to apply an adjustment profile. If a lookup table (“LUT”) is not available that matches parameters passed to scEllipseLUT, this function invokes scEllipseCreate to construct the profile. In FIG. 20, the parameters to scEllipseLUT are:

dx, the x distance or displacement from a corner feature to a pixel center

dy, the y distance from corner to pixel

pV, the unadjusted raster value of the current pixel

cV, the unadjusted raster value of the pixel including the corner feature

cT, the corner type and orientation, such as inside/outside and NE, SE, SW or NW

a, the dimension of a long or major semiaxis of an ellipse used to construct the LUT

b, the dimension of a short or minor semiaxis of an ellipse used to construct the LUT, which may be set to one or another value and not passed

gl, the grey level adjustment parameter, which may be gli for inside corners and glo for outside corners

cInP, an option flag indicating whether corner falls within the pixel pV.

Several global variables (lines 13-16) are used. These include xEllipse, yEllpse, sEllipse and aEllipse. The first three global variables are arrays that implement the corner adjustment profile as a lookup table. The aEllipse parameter is the value of the parameter “a” used to produce the LUT. In lines 17-30, for a given parameter “a”, if a LUT has been loaded or has been persisted, for instance in a disk file, the existing LUT is used. Otherwise, invoking scEllipseCreate produces a new LUT.

Depending on the orientation of the corner, the profile is mirrored across one axis by inverting the sign of one of the displacements for feature corners with “nw” and “se” orientations, and not for the remaining orientations, in lines 31-34. This is computationally efficient.

An adjustment value, dV is calculated by interpolation on the LUT, if a corner is within a predetermined vicinity of a pixel center, in lines 35-45. In this illustration, the predetermined vicinity is a 240 nm square. The LUT value is multiplied by the scale factor gl, lines 46-49, and the value is returned by the function.

The function scEllipseCreate returns three arrays that implement a lookup table, for the parameter “a”. This function could, of course, be implemented for parameters “a” and “b”. It relies on the function ellipse at lines 179-188. Various sections of code support plotting of the corner adjustment profile, including lines 102, 125-142 and 173-177. The function scEllipseCreate effectively cross-correlates an ellipse having semiaxes of “a” and 1 nm with a square pixel with a side bD of 0.080 microns or 80 nm. The size of the pixel is set in line 143. Other functions could readily be substituted for scEllipseCreate to implement various LUTs or to embody different shapes of embellishments. In the function scEllipseLUT, a formula or other calculation could be substituted at line 38 for interpolating against the LUT. At this line, the adjustment profile could be embodied in a formula, LUT, graph or other equivalent logic. Other implementations of an adjustment profile include FIMCTIONS that may be computed without resort to a lookup table.

FIG. 12 depicts a dark feature 1201 and embellishments 1202, 1203 on an exposed background. At the inside and outside corners of the embellishments, the adjustment profile 1106 is applied, e.g., 1204. Effectively, embellishments are applied to the embellishments 1202, 1203. The adjustment profile can be applied along corner bisectors, which correspond in this example to a pair of axes rotated transverse to axes corresponding to edges of the features being printed. Outward from corners, embellishments 1204 are dynamically applied. When the adjustment function is applied to the inside corners at the neck 1205 of the dark figure, energy (“+”) is added from both sides of the neck. When the neck width 1213 (“n”) is decreased below twice the reach of the profile, to less than 214 nm, pixels in the middle can be impacted by adjustments from each side of the neck. This could overcompensate the neck and produce too narrow a feature. Accordingly, a rule can be devised to reduce this effect, such as using only the average contribution of two corner features that contribute the same sign (plus or minus) of adjustment to a particular pixel. In the same way, a small embellishment size 1212 and large neck size 1213 can result in overlapping adjustments of opposing signs. The sum of the adjustments of opposing signs may be used.

In FIG. 8, an elliptical dynamic embellishment is illustrated, such as implemented in the LUT example. The embellishment 810 is oriented along one or more axes that are transverse to axes defined by the edges 604, 614 of the corners being embellished. Alternatively, for instance with a rotated axis system or with diamond shaped pixels, the embellishment could be oriented along one or more axes that are transverse to axes defined by the centers of pixels or the edges of pixels. One aspect of the present invention is dynamically adding an embellishment 810 to a corner. While the embellishment typically is too small or faint to print, grey level values in adjacent pixels may be affected, changing the overall exposure distribution and the pattern resulting in developed resist. In FIGS. 8-10, embellishments 810, 920, 1001 and 1003 are intended to be high aspect ratio embellishments. A rectangle, diamond or parallelogram or another geometric figure with four or more sides may be used as an alternative to an ellipse. High aspect ratio embellishments are well adapted to a pixel-oriented illumination system, as they are likely to span adjacent pixels, in contrast to the compact embellishments 910, 1002 having similar areas. In addition, they can adjust the area at a corner feature with a reduced likelihood of overlap between the contributions of densely packed corners, as compared to compact embellishments. In this context, high aspect ratio means a ratio of at least 4-to-1, preferably 10-to-1, or more between length and width or between major and minor axes, as used in simulations. In simulations, an ellipse having a ratio of 50-to-1 was preferred over an ellipse having a ratio of 25-to-1, which was also workable, both of which were better than a virtual serif having a 10-to-1 ratio. High aspect ratio embellishments can be implemented by lookup tables without incurring the complexity of describing them with vector based geometry. The cross-correlation described above effectively implements dynamic embellishment of a corner feature with a 50-to-1 high aspect ratio ellipse. This embellishment is a corrective feature; the dynamically added embellishment does not appear as an ellipse in a developed resist after exposure.

High aspect ratio embellishments could be adapted to a vector-oriented illumination system, such as a vector e-beam system, if the high aspect ratio embellishments amounted to a specific sweep pattern. High aspect ratio embellishments could be adapted to a scanned illumination system, such as a multi-beam laser or e-beam scanner, if brief illumination flashes were additively superimposed on beam modulation signals.

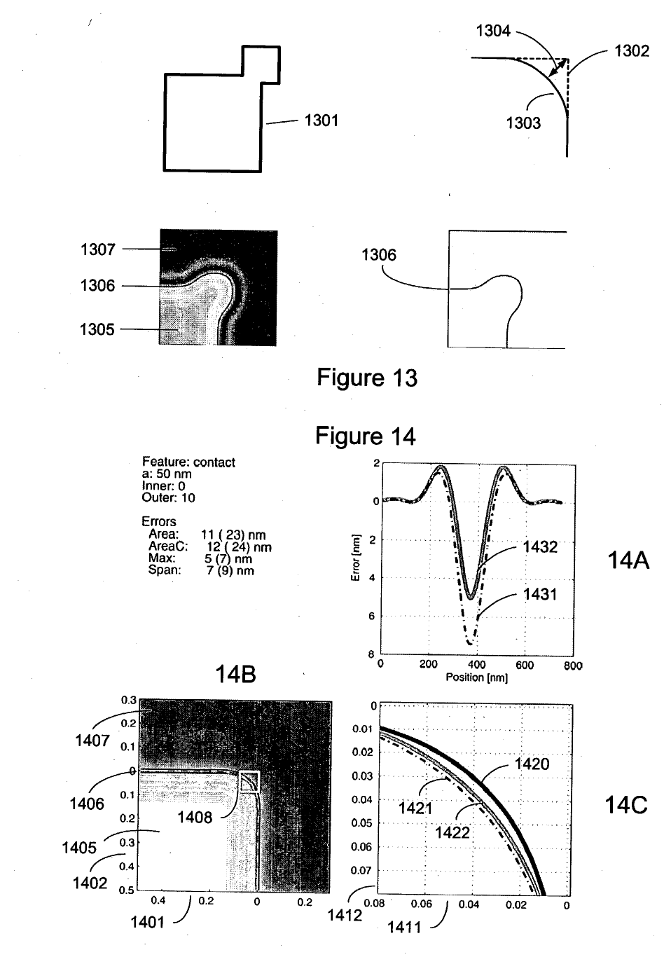

To evaluate the result of applying a corner vicinity exposure adjustment profile, simulations were conducted. FIG. 13 illustrates developing a figure of merit, based on the performance of a state of the art, reference e-beam machine. A shaped electron beam simulator (SEBS) that was developed and implemented in Matlab. The input pattern 1301 to SEBS was a feature with an embellishment. The reference model assumed a Gaussian electron beam with a 50 nm corner pull back for isolated corners. As simulated, an e-beam machine with a single Gaussian distributed vector writing beam generates a rounded corner 1303 with a radius of 100 nm and a pull back 1304 between the desired corner 1302 and the actual corner 1303 of 50 nm. The performance of this reference e-beam machine was simulated to produce iso-intensity curves 1305, 1306, 1307 of an aerial image. A transition area 1306 surrounded an exposed area 1305. Outside the transition area 1307, resist would receive less than a critical dose. An exposure curve 1308 can be extracted from the iso-intensity simulation, to use as a figure of merit, against which simulated results and photomicrographs of applying the adjustment profile can be compared.

The simulations were performed in a Matlab/Sold-C environment. First, the input pattern in vector format (lines/spaces/contacts/islands) was rasterized with an in-house developed Matlab code routine, into a pixel pattern with grey levels corresponding to exposure intensities on individual SLM mirrors of a pattern generator such as depicted in FIG. 1, for four writing passes. FIG. 5 is a sample of this rasterization. Then, the adjustment profile was applied in the raster domain, using the corner position information carried over into the raster domain. (In operation, this information may be carried forward from the vector domain or from subpixel manipulations. Alternatively, design tools that add embellishments to the data could tag corner features for embellishment, instead of adding the embellishments in vector format. This would aid in implementing the intended embellishment and correction, when the pattern generator is able to add embellishments dynamically in parallel with exposing the workpiece.) Pixels in a predetermined vicinity of the corner feature were adjusted according to the adjustment profile and the gli and glo parameters. In order to limit the grey level values to the range [0 1], any values falling below 0 or exceeding 1 were limited. Finally, the continuous range was assigned to 65 discreet grey levels: off, on and 63 intermediate values. The simulations of the optical imaging system from the SLM to the chromium plate of a mask were done with a commercial lithography simulation software, Solid-C from Sigma-C. In the simulations, the illumination system was modeled as an annulus with an inner and outer radius of 0.2 NA and 0.6 NA, respectively. The imaging system was modeled with a fully vectorial optical model as a lens with a reduction of 200, a numerical aperture of 0.82, and an obscuration of 0.16. In order to exclude the influence of uncertainties in a resist model as well as numerical artifacts from interpolation between discreet mesh points in the resist, the aerial image of exposure was used to analyze results instead of the bottom of the resist profile. In the aerial image, the intensity level giving the right size, far away from feature corners, was chosen as dose-to-size.

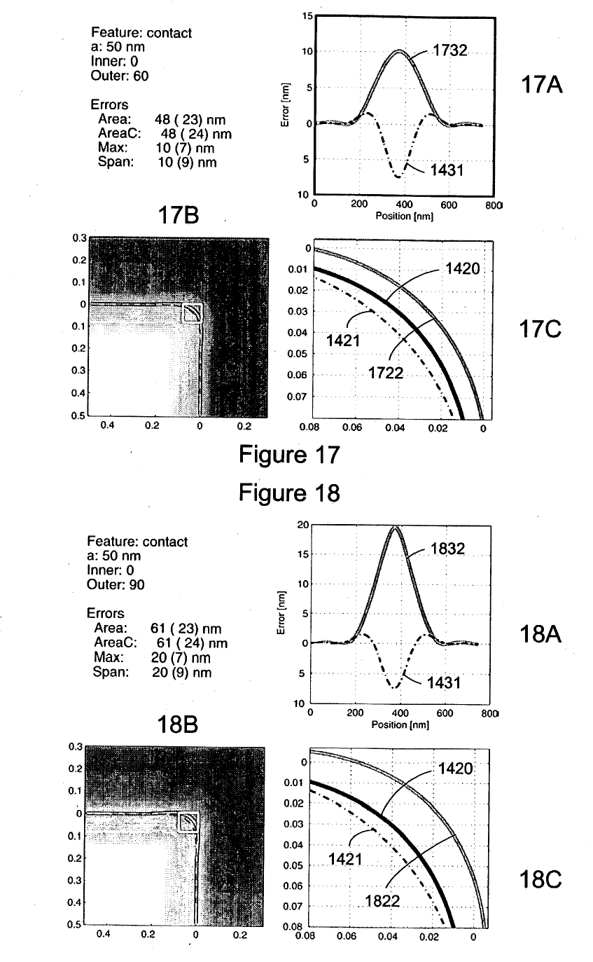

FIGS. 14-18 depict simulation results. In each figure, the parameters and some results are set forth. The “B” frame, such as FIG. 14B illustrates the exposure pattern and a series of curves. The x and y scales 1401, 1402 are expressed in microns. An exposed area 1405 is generally light colored. An unexposed or lightly exposed area 1407 is generally dark colored. A series of curves 1406 have been calculated. One small area 1408 of the curves is expanded in FIG. 14C. The scales 1411, 1412 are again expressed in microns. The reference curve 1420, a dark solid line, corresponds to a reference curve such as 1308. The simulated result of an unadjusted exposure is the dotted curve 1421. The adjustment resulting from the application of the parameters listed as “inner” (gli) and “outer” (glo) is depicted by the grey curve 1422. From figure to figure, the grey curves 1422, 1522, 1622 etc. are renumbered, as they change with the parameters gli and glo. The reference curve 1420 is compared to the unadjusted 1421 and adjusted 1422 curves in FIG. 14A. The x-axis of FIG. 14A tracks the reference curve 1420 from near the y axis 1402 to near the x axis 1401. The y-axis tracks the difference in nanometers from the reference curve 1420. Curve 1431 is the unadjusted exposure and remains constant in FIGS. 14A-19A and is not renumbered. The curves 1432, 1532, 1632 change with the parameters gli and glo.

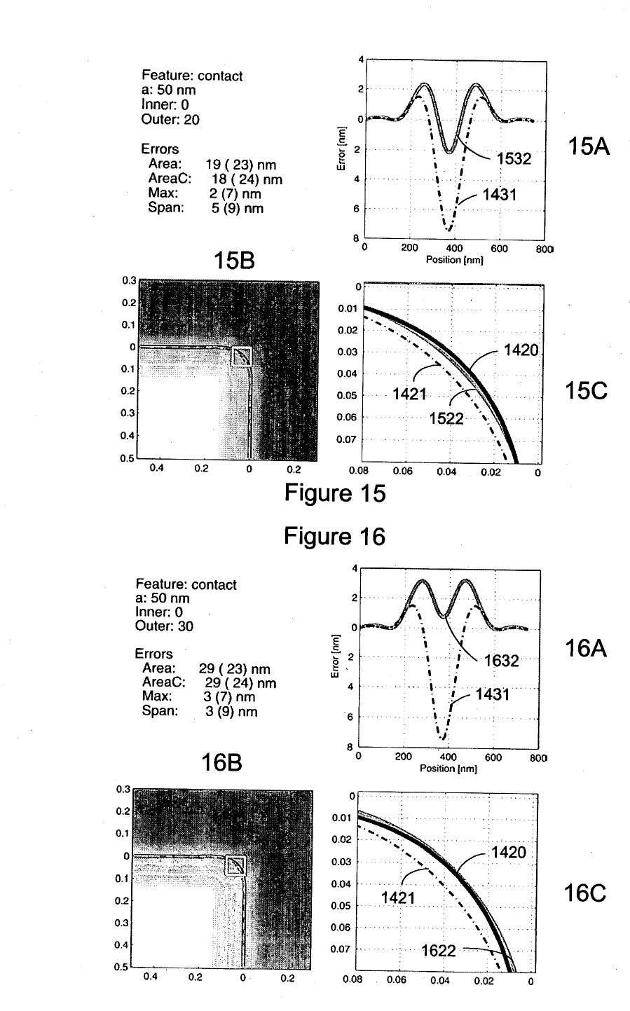

The simulations that appear in FIGS. 14-18 vary the compensation parameter glo from 10 to 90. An analysis of these figures and other analyses performed suggest that a value of 15 would be preferred to minimize area error, 20 to minimize deviation between the reference curve and the adjusted curve 1532 and 30 to minimize the span of the error function. From FIG. 15A, it can be seen that the maximum deviation between the reference curve 1420 and the adjusted curve 1522, 1532 is slightly more than 2 nm of at the corner bisector and overshoot zones. This is a relatively small error for optical emulation of a state-of-the-art e-beam system that has a 40 nm corner pullback with a corner radius of approximately 100 nm. A similar analysis was performed for inside or island corners. A preferred compensation magnitude of 20-30 was selected. At a parameter value of gli=30, the deviation curve shows a maximum error of about 1.5 nm. In terms of area error, the values for the uncompensated and compensated corners are about −35 and 21 nm, respectively.

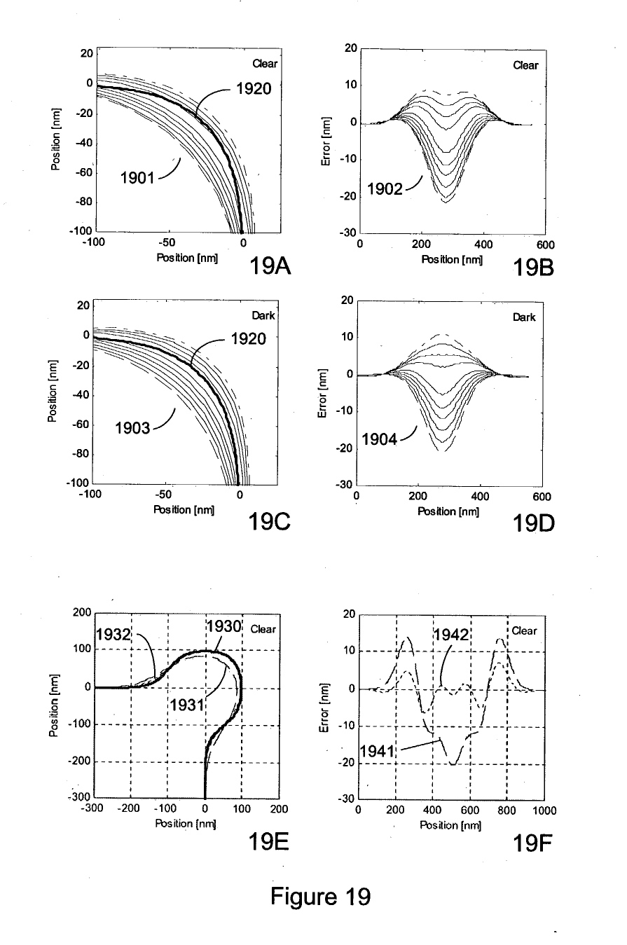

FIG. 19 summarizes the effects of tuning the compensation parameter. Results are presented for both exposed features 19A, 19D and for exposed backgrounds producing dark features 19C, 19B. In FIG. 19A, the reference curve 1920 falls between a series of curves 1901 produced using a range of compensation parameters. The resulting error for this range of compensation curves is depicted in FIG. 19C. The curves 1902 depict the deviation between the reference curve 1920 and the curves 1901. The maximum deviation is approximately along a corner bisector. In FIG. 19B, the reference curve 1920 again falls between a series of curves 1903. The resulting error for this range of compensation curves is depicted in FIG. 19D by curves 1904, which depicts deviation between the reference curve 1920 and curves 1903. Again, the maximum deviation is approximately along a corner bisector.

Exposure of a corner with an embellishment, similar to the one depicted in FIG. 2, is illustrated by FIGS. 19E, 19F. In FIG. 19E, the reference curve is 1930. The exposure iso-contour without compensation is 1931. With compensation, the closely dotted iso-contour line 1932 nearly matches the reference curve 1930. The deviation is depicted in FIG. 19F, which shows why the reference and corrected curves are indistinguishable in many areas of FIG. 19F. The uncorrected curve 1941 has a deviation of as much as 20 nm from the reference curve. The corrected curve 1942 has deviation lobes of plus and minus 5 nm, and a substantial portion of the corrected curve is within 2-3 nanometers of the reference curve.

When corners of embellishments are very close or dense, two types of problems arise. One involves a very narrow neck and the other very narrow notch. With a narrow neck, the neck tends to be overcompensated and pinched off, to fall outside of specifications. This problem can be reduced by applying the rule that only the average of overlapping adjustment functions are be applied or that some other fraction of the sum of overlapping adjustment functions is applied. With a narrow notch between embellishments, for instance twin serifs at the end of a narrow line, the embellishments tend to round into each other. Modification of parameters can adapt a process to the narrow notch case, but the process may then produce worse results in other cases, such as isolated corners. Alternatively, the application of the adjustment profile might be altered in cases where a narrow notch was detected within the predetermined vicinity. Adjustments to outside corners on opposite sides of the notch could be reduced or handled by a profile having a different orientation, such as parallel to the notch orientation, to minimize fill in at the notch. Analysis of the test cases for dense corners found parameter values of gli=30 and glo=30 to produce the largest number of test cases within error specification. The most difficult test case had a relatively narrow line and large embellishment, producing a narrow notch.

A line end is an important kind of corner. FIGS. 23A, 23B, 23C depict a line end, both for of an exposed feature and for a dark feature against an exposed background. The ideal, squared off line end 2301 is not quite attained by the reference curves 2302, 2303. The reference e-beam writer has some pullback at the corners 2302 and some line shortening for narrow lines 2303. Without corner enhancement, an image produced with an SLM has line end shortening properties depicted by curves 2311, 2321 that are similar to the reference curve 2310 for line widths as narrow as 300 nm. When corner feature enhancement is applied, the image produced with the SLM has line end shortening properties depicted by curves 2312, 2322 that are similar to the reference curve for line widths as narrow as 200 nm.

Scanning electron microscope pictures of patterns developed and resist were taken. However, quantitative comparisons between measured and modeled data proved difficult.

From the preceding description, it will be apparent to those of skill in the art that a wide variety of systems and methods can be constructed from aspects and components of the present invention. One embodiment is a method of providing process control in a rasterized data domain. The system operator can vary the exposure at corner features according to this method. The method includes providing a corner-vicinity exposure adjustment profile. The exposure adjustment profile is applied to a corner feature in rasterized exposure pattern data to adjust exposure to radiant energy of a work piece. The exposure is adjusted within a predetermined vicinity of the corner feature. A pattern is then generated on the work piece using the adjusted exposure pattern data. One aspect of this embodiment is that the corner-vicinity exposure adjustment profile may correspond to a cross-correlation of a high aspect ratio embellishment and a representative pixel area. The representative pixel area may be a pixel in the object plane of an SLM or other modulating device or a pixel in the image plane at the surface of the workpiece, either in an image or intensity domain. This exposure profile may be implemented as a lookup table or a FIMCTIONS that is calculated. At high aspect ratio may be at least 4-to-1, 10-to-1, 25-to-1 or 50-to-1. Alternatively and more generally, the corner vicinity exposure adjustment profile may correspond to a high aspect ratio embellishment.

A corner-vicinity adjustment profile may produce exposures that are essential independent of where the corner feature falls within a pixel area. Alternatively, the corner-vicinity adjustment profile may produce exposures having dependence on location of the corner feature within a pixel area of plus or minus 1 nm or better. Another aspect of this embodiment is that the applying and generating steps may proceed in parallel as a stream of rasterized exposure pattern data is processed. The rasterized exposure pattern data may be generated from vector pattern data. The vector pattern data may be rasterized in parallel with the applying in generating steps. The underlying vector pattern data remains unmodified through application of the exposure adjustment profile in the raster domain. A further aspect of this embodiment includes the details of how the adjustment profile is applied relative to a corner feature and to the center of a pixel. These details are described above.

Another embodiment is a method of dynamically adding a high aspect ratio embellishment at one or more corner features identified within a stream of rasterized data. This method includes superimposing a high aspect ratio embellishment at the corner and adjusting exposure in a predetermined vicinity of the corner feature corresponding to the superimposed high aspect ratio embellishment. Aspects of this embodiment may be as in the prior embodiment. Both embodiments may share adjusting exposure further by applying an adjustment parameter to control the extent of exposure adjustment.

A further embodiment is a method of implementing of dynamically added high aspect ratio embellishment at a corner feature in a pixel-oriented exposure system. This method includes applying a corner-vicinity exposure adjustment profile to adjust exposure values of pixels within a predetermined vicinity of a particular corner feature, corresponding to a dynamically added high aspect ratio embellishment at the particular corner feature. It may further include generating a pattern on a work piece utilizing the adjusted pixel exposure values. Aspects of this embodiment may be as in the prior embodiments.

Yet another embodiment is a method of exposing a workpiece using a pattern generator oriented to pixels, including exposing a resist layer in at least four exposure passes. The pixels are staggered such that parallel axes constructed through centers of the pixels exposed in at least three of the four exposure passes are not coincident. The exposure passes produce an overlap of at least four pixels, defining an overlap area. The overlapping pixels have pixel centers. The pixel centers have an essentially uniform angular distribution around the overlap area center. The pixel centers also may be essentially equidistant from the overlap area center. Alternatively, the pixel centers may be essentially equidistant from the overlap area center but not uniform in angular distribution. The pixel orientation may either be a physical arrangement of modulators, such as micromirror, or a logical organization of positions to control modulation of an exposing radiation.

Another aspect of the present invention is a method of qualifying a pattern generator for use in a fabrication process. Alternatively, this method can be described as a method for matching a pattern generator to another pattern generator, especially another pattern generator that has previously be qualified for use in a fabrication process. The pattern generator may be used either to produce masks or for direct writing. Workpieces is a generic term that can refer to either masks or devices on which exposed patterns are generated. According to this method, patterns are exposed on workpieces by the pattern generators. The patterns may be exposed on resist, for instance. The method involves comparing the exposed pattern properties. The pattern properties could be compared either as latent exposures or in a developed resist. One of the pattern generators, to be adjusted, uses process control parameters. For instance, the corner-vicinity adjustment profile can be used to adjust the process. The method involves adjusting one or more process control parameters to match the exposed patterns. The exposed patterns can either appear on the workpiece that is directly patterned by the pattern generator or on a workpiece that is exposed using a mask that has been patterned by the pattern generator. That is, the exposed patterns of interest can be directly produced by the pattern generator or can be produced by a mask that has been produced by the pattern generator. This method may involve changing raster domain data in the pattern generator being adjusted. The method may be applied either on a fixed basis, where process control parameters have been selected to match one pattern generator to the other generally or for a specific product type, or on a variable basis, where process control parameters are adjusted for a particular pattern generator in a particular production run, based on exposed pattern properties measured from the particular pattern generator in the particular production run. As described above, process parameters may relate to corner feature exposure properties. The comparing may be done by simulation, at least to produce the fixed basis application. A specifically adapted simulation could be used for comparison, matching the simulation to properties measured from the particular pattern generator in a particular production run. Alternatively, the comparing may be done experimentally. For instance, experimental exposures may be produced directly using the pattern generator or indirectly using a mask produced using the pattern generator.

The present invention further includes logic and resources in a data stream processor to implement any of the methods described above. It extends to a pattern generator including such logic and resources. It also includes as an article of manufacturer a memory impressed with digital logic to implement any of the methods described above. It extends to a pattern generator into which the digital logic from the article of manufacturer is loaded.

While the present invention is disclosed by reference to the preferred embodiments and examples detailed above, it is understood that these examples are intended in an illustrative rather than in a limiting sense. It is contemplated that modifications and combinations will readily occur to those skilled in the art, which modifications and combinations will be within the spirit of the invention and the scope of the following claims.

We claim as follows:

1. A method of providing process control, in a rasterized data domain, of exposure at corner features, the method including:
providing a corner-vicinity exposure adjustment profile;
applying the exposure adjustment profile to a corner feature in rasterized exposure pattern data to adjust exposure to radiant energy of a workpiece within a predetermined vicinity of the corner feature; and
generating a pattern on the workpiece utilizing the adjusted exposure pattern data.

2. The method of claim 1, wherein the corner-vicinity exposure adjustment profile corresponds to a cross-correlation of a high aspect ratio embellishment and a representative pixel area.

3. The method of claim 1, wherein the corner-vicinity exposure adjustment profile produces adjustments that are essentially independent of where the corner feature falls within a pixel area.

4. The method of claim 1, wherein the corner-vicinity exposure adjustment profile produces exposures having dependence on location of the corner feature within a pixel area of plus or minus 1 nm or better.

5. The method of claim 2, wherein the representative pixel area corresponds to a cross-section of an element controlling exposure of a pixel.

6. The method of claim 2, wherein the representative pixel area corresponds to a cross-section of a projection onto the workpiece of an element controlling exposure of a pixel.

7. The method of claim 1, wherein the corner-vicinity exposure adjustment profile corresponds to a combination between a high aspect ratio embellishment and a representative pixel area.

8. The method of claim 1, wherein the corner-vicinity exposure adjustment profile corresponds to a high aspect ratio embellishment to be superimposed at the corner feature.

9. The method of claim 1, wherein the corner-vicinity exposure profile is implemented as a lookup table.

10. The method of claim 2, wherein the corner-vicinity exposure profile is implemented as a lookup table.

11. The method of claim 1, wherein the applying and generating steps proceed in parallel as a stream of rasterized exposure pattern data is processed.

12. The method of claim 11, wherein the rasterized exposure pattern data is generated from vector pattern data and the vector pattern data is not modified by the applying step.

13. The method of claim 1, wherein the applying step further includes, for particular pixels in the rasterized exposure pattern data, identifying one or more corner features within the predetermined vicinity of the particular pixels and processing the corner features to determine the adjusted exposure for the particular pixels.

14. The method of claim 1, wherein the applying step further includes, for particular corner features in the rasterized exposure pattern data, identifying one or more pixels having centers within the predetermined vicinity and processing the pixels to determine the contribution of the particular corner feature to the adjusted exposure for the identified pixels.

15. The method of claim 1, wherein the applying step further includes, for particular corner features in the rasterized exposure pattern data, identifying one or more pixels within the predetermined vicinity and processing the pixels to determine the contribution of the particular corner feature to the adjusted exposure for the identified pixels.

16. A method of dynamically adding a high aspect ratio embellishment at one or more corner features identified within a stream of rasterized data, the method including:
superimposing a high aspect ratio embellishment at the corner feature; and
adjusting exposure in a predetermined vicinity of the corner feature corresponding to the superimposed high aspect ratio embellishment.

17. The method of claim 16, wherein adjusting exposure in the predetermined vicinity includes applying a corner-vicinity exposure adjustment profile to determine exposure adjustment corresponding to relative locations of the corner feature and a particular pixel area.

18. The method of claim 17, wherein the corner-vicinity exposure adjustment profile corresponds to a cross-correlation of the high aspect ratio embellishment and a representative pixel area.

19. The method of claim 17, wherein the corner-vicinity exposure profile is implemented as a lookup table.

20. The method of claim 16, wherein the high aspect ratio embellishment has an aspect ratio of at least four to one.

21. The method of claim 16, wherein the high aspect ratio embellishment has an aspect ratio of at least ten to one.

22. The method of claim 16, wherein the high aspect ratio embellishment has an aspect ratio of at least 25 to one.

23. The method of claim 16, wherein the high aspect ratio embellishment has an aspect ratio of at least 50 to one.

24. The method of claim 20, wherein edges of the corner feature are oriented to first and second axes and the high aspect ratio embellishment is oriented transverse to the first and second axes.

25. The method of claim 16, wherein adjusting exposure further includes applying an adjustment parameter to control the extent of exposure adjustment.

26. The method of claim 18, wherein adjusting exposure further includes applying an adjustment parameter in combination with the corner-vicinity exposure adjustment profile.

27. A method of implementing a dynamically added high aspect ratio embellishment at a corner feature in a pixel-oriented exposure system, the method including:
applying a corner-vicinity exposure adjustment profile to adjust exposure values of pixels within a predetermined vicinity of a particular corner feature, corresponding to a dynamically added high aspect ratio embellishment at the particular corner feature; and
generating a pattern on a workpiece utilizing the adjusted pixel exposure values.

28. A method of exposing a workpiece using a pattern generator having pixels, including exposing a resist layer in at least three exposure passes, wherein the pixels are staggered such that parallel axes constructed through centers of the pixels exposed in at least three of the four exposure passes are not coincident.

29. The method of claim 28, wherein said exposure passes producing an overlap of pixels defining an overlap area, and the pixel centers have an essentially uniform angular distribution around the overlap area center.

30. The method of claim 29, wherein the pixel centers are essentially equidistant from the overlap area center.

31. The method of claim 28, wherein said exposure passes producing an overlap of pixels defining an overlap area, and the pixel centers are essentially equidistant from the overlap area center.

32. A method of matching two pattern generators by adjusting pattern generation one or more control parameters of at least one of said pattern generators, the method including:
comparing exposed pattern properties of patterns produced on workpieces using the pattern generators, one of which uses said process control parameters;
adjusting said process control parameters until the exposed pattern is essentially matched; and
changing the raster domain data in at least one of the pattern generators according to said process control parameters.

33. The method of claim 32, wherein said process parameters relate to corner feature exposure properties.

34. The method of claim 32, wherein the comparing is done by simulation.

35. The method of claim 32, wherein the comparison is done by experimental exposure.

36. The method of claim 32, wherein the pattern generators are mask writers.

37. The method of claim 32, wherein the pattern generators are direct writers.

38. The method of claim 32, wherein comparing is based on patterns produced using the pattern generators to expose the workpieces.

39. The method of claim 32, wherein comparing is based on patterns produced using the pattern generators to expose masks that are used to expose the workpieces.

40. A method of exposing a workpiece using a pixel-oriented pattern generator, including exposing a resist layer in at least three exposure passes, wherein said exposure passes producing an overlap of pixels defining an overlap area, and centers of the pixels that overlap have an essentially uniform angular distribution around the overlap area center.

41. The method of claim 40, wherein the pixels are physical elements of a modulator.

42. The method of claim 40, wherein the pixels are logical positions for modulation of an exposing radiation.
